(19) United States
(12) Patent Application Publication
(10) Pub. No.: US 2004/0142665 A1
(43) Pub. Date: Jul. 22, 2004

(54) Method and apparatus for diversity combining using a least squares approach

(76) Inventors: Apostolos Papathanasion, Ilioupolis (GR); Aristidis Posonidis, Holargos (GR); Konstantinos Aretos, Ag. Dimitrios (GR); Emmanuel Frantze Skakis, Ilioupolis (GR)

Correspondence Address: Hung Chang LIN, 8 Schndler Ct., Silver Spring, MD, 20903, US

(21) Appl. No.: 10/347,056

(22) Filed: Jan. 21, 2003

(51) Int. Cl. H04B 7/14; H04B 1/02; H03C 7/02; H04B 7/02

(52) U.S. Cl. 455/101; 455/25

(57) ABSTRACT

A method and apparatus for controlling an antenna array for wireless communication are described. The method is applied at a receiver and it uses a least squares algorithm for recovering the spatial signature of each of a plurality of signals transmitted simultaneously by a plurality of transmitters. The spatial signature is used for controlling the antenna array in order to achieve directional reception in a wireless communication system and suppress co-channel interference. The method can be used either in single transmitter configurations for smart antenna reception or multi-transmitter configurations for space-division multiple access systems. Furthermore, it can be used in conjunction with multi-carrier modulation signaling.

### BACKGROUND OF THE INVENTION

(1) Field of the Invention

The invention relates to wireless communications, in particular to method for controlling an antenna array for burst wireless communications

(2) Brief Description of Related Art

In the area of burst wireless communications the directional signal transmission and reception enhance all the performance metrics of the communication links such as range, throughput rate, emitted signal power, power dissipation, as well as link reliability and interference immunity. Directionality is achieved by employing an antenna array controlled by a beamformer logic at the transmitter site and a signal combiner logic at the receiver site. Antenna arrays can also be coupled with logic for supporting multiple communication links with spatially separated users that share the same spectrum and time frame. For example, spatial division multiple access (SDMA) systems are based on this notion. The above pieces of logic can be modeled in many different ways [1]. However, incorporating high performance adaptation techniques in practical applications is a highly non-trivial task because of the computational complexity factor.

A number of different methods for diversity combining and beamforming for burst wireless communications systems have been proposed. However, these methods suffer from one or more weaknesses such as the need of unrealistic modeling assumptions, high computational complexity, slow convergence and the need of coupling with ad-hoc algorithms that alleviate the above.

In [2] an algorithm for diversity combining is proposed. The performance of this algorithm is very good but the required computational complexity is high since the algorithm is based on joint space-frequency domain signal processing.

In [3] and [4], two categories of algorithms for diversity combining and beamforming are reviewed. In the first category, the direction of arrival (DOA) of the beam needs to be identified at the receiver. This presents many deficiencies. First, DOA estimation is an extremely computation intensive process that cannot be implemented efficiently in the current art of semiconductor technology, thus it cannot find applications in high volume consumer products. Second, the DOA estimation methods are very sensitive to model imperfections such as antenna element intervals and antenna array geometry. Third, the number of antenna elements in the antenna array limits the number of multipaths and interferers DOA based methods can cope with.

In the second category, a training sequence is required along with an estimation of the correlation with this training sequence and the input signal correlations. Although the problems of the algorithms in the previous paragraph are avoided, the need for estimating the correlations of the input signals introduces a low algorithm convergence rate, especially in relation to multicarrier wireless communication systems. For instance, averaging over a particular subcarrier requires multiple multicarrier symbols.

### SUMMARY OF THE INVENTION

An object of the present invention is to provide a method for controlling an antenna array appropriate for burst wireless communications. Another object of this invention is to provide spatial feature processing, performed independently of the time or frequency. Still another object of this invention is to provide a computationally efficient framework applicable to a wide spectrum of applications. This method exhibits smart antenna characteristics for the receiver including co-channel interference suppression and multi-user support. Also it can be applied in burst wireless systems employing the Orthogonal Frequency Division Multiplexing (OFDM) signaling scheme.

These objects are achieved by using a least squares algorithm for controlling an antenna array in order to achieve directional reception and suppress co-channel interference in a burst wireless OFDM communication system. The invention also features novel physical layer processing for an SDMA system.

The advantages of this invention are as follows:

Enables non-line of sight communication.

Improves the reliability and performance of the wireless communication system in the presence of interference.

Exploits spatial diversity in order to support multiple users at the same frequency spectrum and time frame, thus it increases dramatically the communication capacity.

Low computational complexity allowing the use of this method in devices targeting the consumer market.

Fast convergence.

No assumption of the statistical characteristics of the signal or the channel is necessary.

No assumption about the antenna array geometry is necessary, while the method is immune to antenna element placement and element interval inaccuracies.

### BRIEF DESCRIPTION OF THE DRAWINGS

FIG. 1. Block diagram of a wireless communications receiver employing multiple diversity combiner means according to the present invention

FIG. 2A. Flowchart of operation for a diversity combining means according to the invention;

FIG. 2B. Explanatory details table for the diversity combining means in FIG. 2A

FIG. 3. Frequency domain diversity combiner for multiple user configuration

FIG. 4. First time domain diversity combiner for multiple user configuration

FIG. 5. Second time domain diversity combiner for multiple user configuration

FIG. 6. Frequency domain diversity combiner for single user configuration

FIG. 7. First time domain diversity combiner for single user configuration

FIG. 8. Second time domain diversity combiner for single user configuration

FIG. 9. Simplified frequency domain diversity combiner for multiple user configuration

FIG. 10. Simplified first time domain diversity combiner for multiple user configuration

FIG. 11. Second simplified time domain diversity combiner for multiple user configuration

### DETAILED DESCRIPTION OF THE INVENTION

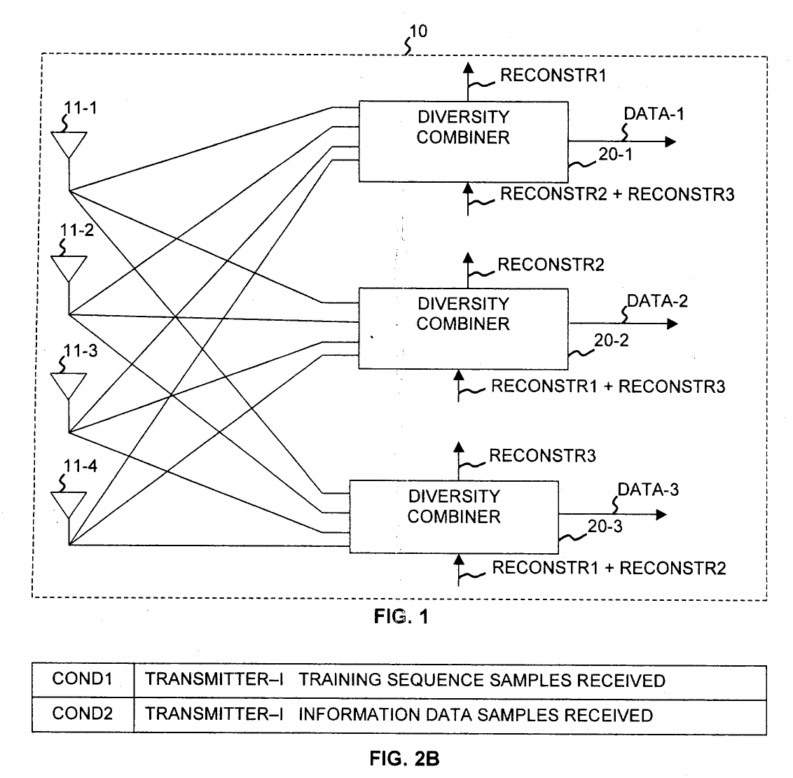

With reference to FIG. 1, a wireless communications receiver 10 in accordance with a first preferred embodiment of the present invention receives a plurality of M input signals, for example M=4, using an array of antenna elements 11-1 though 11-4. Each of the signals received in the antenna array is a sum of a plurality of K, for example K=3, useful information signals, as well as noise and/or interference signals. The useful information signals are generated by respective transmitter devices and they share essentially the same frequency spectrum. Each information signal is characterized by a frame comprising a known training sequence and an information data sequence. The transmitting devices and the receiver 10 are synchronized so that the receiver is aware of the starting time instants and ending time instants of the training sequences and the information data sequences of all transmitting devices. Also, the training sequences used for channel estimation are known to the receiver that performs a joint channel estimation for the channel pertaining to each transmitting device. The receiver 10 further comprises a plurality of diversity combiners 20-1 through 20-3. A diversity combiner 20-I, where I takes values in the range 1 through 3, is coupled to receive input from all M antenna elements in the antenna array constituting a sequence of M-element received samples and produce as output a sequence of scalar estimated logic levels Data-I and a sequence of M-element reconstructed input samples ReconstrI. Also, 20-I is coupled to receive as input the sum of the reconstructed input samples of all diversity combiners in the receiver excluding the I^{th} one. Note that a receiver in accordance to this preferred embodiment of the present invention may use any number M>1 of antenna elements in the antenna array, while the number of diversity combiners K can take any value in the set 1, 2, . . . , M. As an example, the description in FIG. 1 uses the numbers M=4 and K=3.

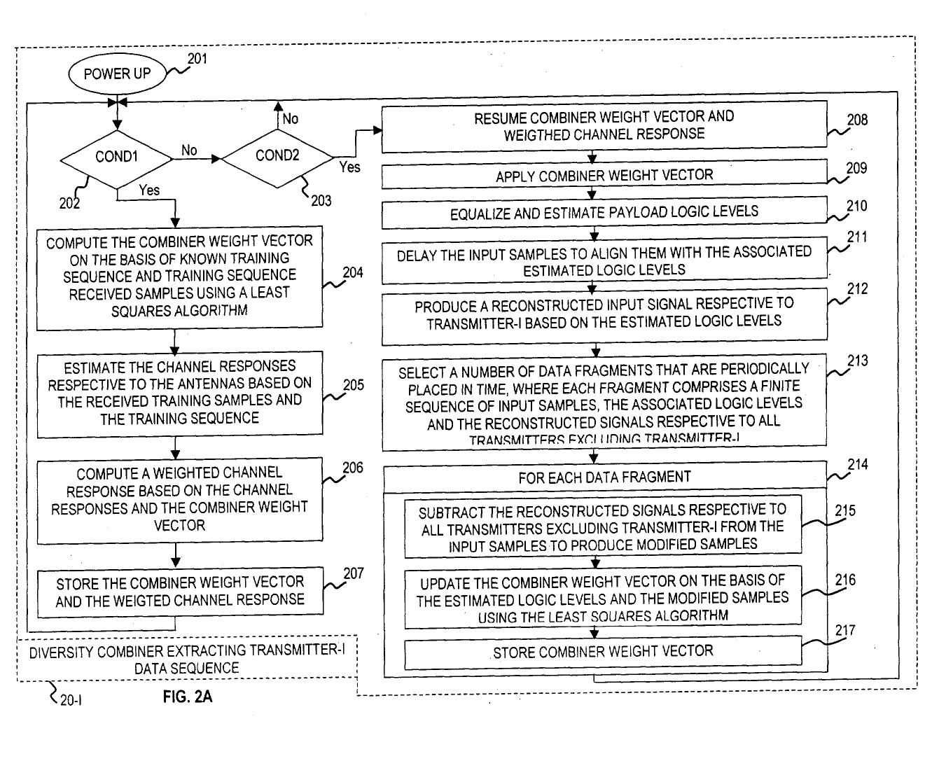

With reference to FIG. 2A and FIG. 2B, a detailed flowchart of the operation of the diversity combiner 20-I is used by the receiver in FIG. 1. The flowchart begins with power up 201. When a sequence of received training samples is received in block 202 a sequence of four-step processing takes place. In the first step 204 a combiner weight vector of length M is computed using a least squares algorithm based on the sequence of received training samples and the known training sequence. In the second step 205 the channel responses respective to each antenna element of the antenna array are estimated on the basis of the received training samples and the known training sequence. In the third step 206 a weighted channel response is computed based on the said channel responses and the combiner weight vector. In the fourth step 207 the combiner weight vector and the weighted channel response are stored in a memory means. When a sequence of received information data samples is received in block 203 a sequence of seven-step processing takes place. In the first step 208 the combiner weight vector and the said weighted channel response are resumed from the memory means. In the second step 209 a sequence of scalar weighted samples is computed on the basis of the received M-element information data samples and the combiner weight vector. In the third step 210 the sequence of weighted samples are fed to a channel equalization unit and the equalized data is properly sliced to produce a sequence of estimated logic levels. In the fourth step 211 the M-element input samples are properly delayed to achieve time alignment with their respective estimated scalar logic levels. In the fifth step 212 the sequence of estimated scalar logic levels is properly transformed to produce a sequence of M-element reconstructed input samples. In the sixth step 213 the sequence of estimated logic levels is fragmented into a number of equal length data fragments and then the data fragments are periodically sampled. In particular for multi-carrier communication systems, a fragment may correspond to one multi-carrier symbol. Furthermore, similar fragmentation and sampling is also applied on the input information data samples and the reconstructed input data samples in a way so that the sampled fragments of the received information data samples and the reconstructed input samples correspond and are time aligned to the respective estimated logic levels. In the seventh step 214 the data of each fragment is processed following a sequence of three sub-steps. In the first one 215 a fragment of modified information data samples is produced based on the respective received information data samples and the reconstructed input samples generated by all diversity combiners excluding 20-I. In the second one 216 the combiner weight vector is updated using the least squares algorithm based on the sequence of modified information data samples and the respective fragment of estimated logic levels. In the third one 217 the updated combiner weight vector is stored back in the memory means.

The flowchart described above is appropriate both for multi-user communication using directional reception and co-channel interference (CCI) suppression of single carrier or multi-carrier signals. Examples of the least squares algorithm are the Recursive Least Squares (RLS) algorithm and the Householder algorithm [1]. Furthermore, with reference to FIG. 1, the diversity combiners 20-1 through 20-3 may share a common least squares means on a time-sharing basis. This reduces the computational complexity of the receiver while it imposes a constraint in the period of fragment sampling affecting the convergence speed of the algorithm.

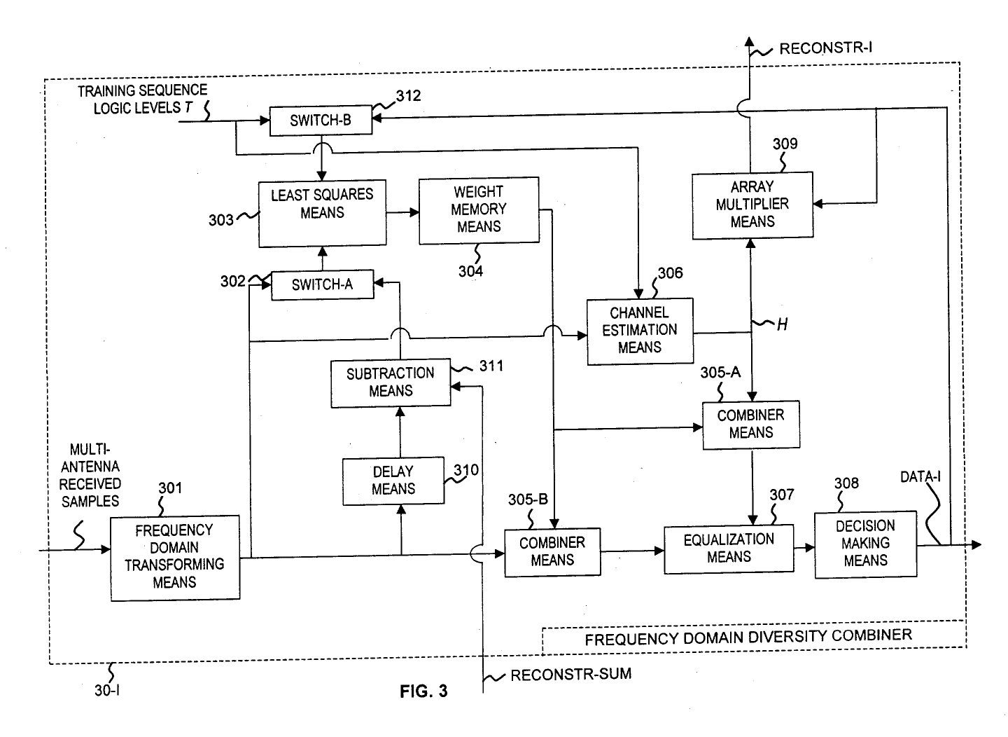

With reference to FIG. 3, a diversity combiner 30-I in accordance with a second preferred embodiment of the present invention performs the combining in frequency domain, while it uses a frequency domain training sequence T for computing the combiner weight vector. Diversity combiner 30-I can be used for multi-user communication. In this case, there is one frequency domain training sequence T_{I} for each user I, I=1,2, . . . K. In any case, for simplicity the training sequence will be denoted with T. A frequency domain transforming means 301 is coupled to receive as input the sequence of M-element samples from the antenna elements and produce a sequence of M-element frequency domain samples. A switch-A means 302 controls a data input X, while a switch-B means 312 controls a decision input of the least squares means 303. X is a matrix of size N×M and the decision input is a vector length N, where N is the length of the known training sequence. The M-element frequency domain samples respective to the training sequence and the known training sequence levels T are fed to the least squares means 303 through switch-A 302 and switch-B 312 respectively. The least squares means minimizes the quantity ||Xw−T||² with respect to the M-element combiner weight vector w. The resulting vector w is stored in memory means 304. Further, the N×M matrix X and the vector T of length N are also fed to a channel estimation means 306 that produces an estimate of the frequency domain channel responses arranged in the matrix H_{I} of size N×M for each user I=1,2, . . . K. For simplicity, the channel response will b denoted with H. A combiner means 305-A is coupled to receive as input the sequence of the M-element frequency domain channel responses along with the combiner weight vector w resumed from the weight memory means 304 and produces a scalar weighted channel frequency response for use by the equalization means 307 operating on the information data. The M-element frequency domain samples respective to the information data sequence along with the combiner weight vector resumed from the weight memory means 304 are fed to the combiner means 305-B in order to produce a scalar sequence of weighted data samples. Note that the combiner means 305-A and 305-B are identical. A channel equalization means 307 is coupled to receive as input the said weighted channel frequency response and the sequence of the weighted data samples and produce as output a sequence of equalized data. A decision making means 308 is coupled to receive as input the sequence of equalized data and produce as output a sequence of estimated logic levels Data-I. An array multiplier means 309 multiplies the sequence of estimated logic levels with the M×N channel matrix H and produces as output a sequence of M-element reconstructed input samples Reconstr-I. Also, the sequence of the estimated logic levels is fed to the switch-B means 312. A delay means 310 is coupled to receive as input the sequence of frequency domain samples and delay them properly to align them in time with the sequence of reconstructed input samples. A subtraction means 311 subtracts the sum Reconstr-Sum of the reconstructed input samples produced by all diversity combiners in the receiver excluding 30-I from the delayed frequency samples to produce a sequence of modified samples. The produced sequence is fed to the switch-A means 302. The switch-A means 302 and switch-B means 312 function as gating circuits for the sequence of modified samples and the estimated logic levels respectively and they feed the least squares means 303 with periodical fragments of data. On the basis of each fragment of input data, the least squares means 303 produces a new updated value of the combiner weight vector w and stores it in the weight memory means 304. When the frequency domain diversity combiner 30-I is used for multi-carrier signals the said periodical fragments of data can be periodical multi-carrier symbols.

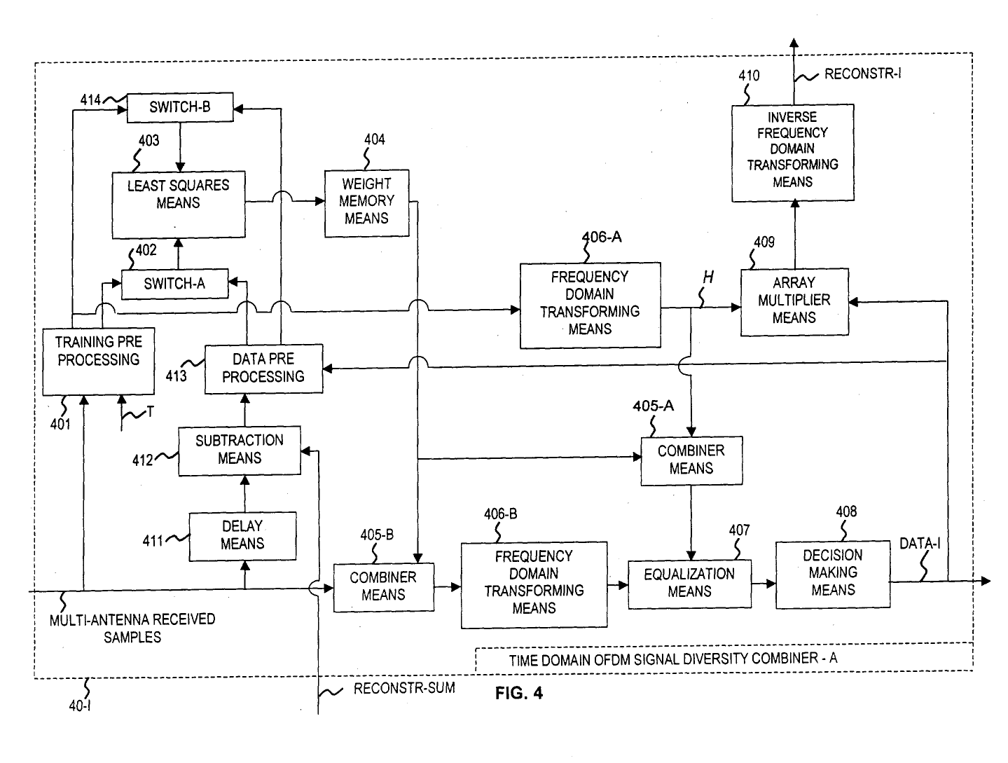

With reference to FIG. 4, a diversity combiner 40-I in accordance with a third preferred embodiment of the present invention performs the combining in time domain while it uses a frequency domain training sequence T for computing the combiner weight vector. The diversity combiner 40-I also can be used for multi-user communication. A training sequence pre-processing means 401 is coupled to get as input the received sequence R of M-element samples from the antenna elements and estimate the time responses H of the M channels respective to the antennas, where H is a matrix of size N×M and N is the length of the training sequence T. For example, H can be computed as follows:

H=B·R (1)

where B is the inverse (or, in case of singularity, the pseudo-inverse) of the matrix

A=D_{I}·diag{T}·D_{F} (2)

with D_{I},D_{F} being the inverse and forward transform domain conversion matrices of size N×N and diag{T} is an N×N diagonal matrix having the elements of the frequency domain training sequence T in its diagonal. For example, if 40-I is used in relation with orthogonal frequency domain multiplexing (OFDM) signaling N can be equal to the OFDM symbol length and D_{I},D_{F} will represent the inverse and forward Fourier transform matrices respectively. Equivalently, matrix B can be computed as follows:

$$B = {\sum }_{n ∈ S}^{} \frac{1}{{T}_{n}} {d}_{n} {d}_{n}^{* T} \qquad ( 3 )$$

where Tₙ denotes the n^{th} sample of the training sequence, S is the set of indices corresponding to non-zero training samples, “T” denotes transposition, “*” denotes complex conjugation, and dₙ denotes the n^{th} column of the matrix D_{I}. The training sequence pre-processing means 410 computes also a vector t of combining samples on the basis of H using for example the formula:

$$t = {[ {t}_{1} {t}_{2} ⋯ {t}_{N} ]}^{T} , where {t}_{n} = {\sum }_{m = 1}^{M} {\vert {h}_{nm} \vert}^{2} , n = 1 , … , N \qquad ( 4 )$$

and hₙₘ, n=1, . . . , N, m=1, . . . , M, are the elements of matrix H. The least squares means 403 receives H and t through switch-A 402 and switch-B 414 respectively and after normalizing H it produces the combiner weight vector w that minimizes the quantity ||Xw−t||². X is the result of normalizing H using for example:

X=Γ·H (5)

where Γ is a diagonal matrix Γ=diag[γγ₂ . . . γ_{N}], γₙ=\sqrt{maxt/tₙ}, n=1, . . . , N, with maxt being the maximum of tₙ, n=1, . . . , N. Alternatively, the training pre-processing means 401 can be configured to compute a vector of combining samples ν according to

ν=A·[1/γ₁ 1/γ₂ . . . 1/γ_{N}]^{T} (6)

while the switch-A 402 is coupled to get as input the received samples R and the least squares means 403 is configured to minimize the quantity ||Rw−ν||². The combiner weight vector produced by the means 403 is stored in the weight memory means 404. Further, each of the M channel responses of H is fed to a frequency domain transforming means 406-A, the output of which is fed along with the combiner weight vector w resumed from the weight memory means 404 to a combiner means 405-A. Means 405-A produces a weighted channel frequency response to be used by equalization means 407. The sequence of M-element received samples respective to the information data sequence along with the combiner weight vector resumed from the weight memory means 404 are fed to the combiner means 405-B in order to produce a scalar sequence of weighted data samples. Note that combiner means 405-A and 405-B are identical. The frequency domain transforming means 406-B transforms the sequence of weighted samples to a sequence of frequency domain samples. Note that the frequency domain transforming means 406-A and 406-B are identical. A channel equalization means 407 is coupled to receive as input the said weighted channel frequency response and the sequence of the weighted data samples and produce as output a sequence of equalized data. A decision making means 408 is coupled to receive as input the sequence of equalized data and produce as output a sequence of estimated logic levels Data-I. An array multiplier means 409 multiplies the logic levels Data-I with the channel response matrix Hi and produces as output a sequence of M-element reconstructed input samples in the time domain. An inverse frequency domain transforming means 410 transforms the frequency domain reconstructed input samples to the time domain reconstructed input samples Reconstr-I. A delay means 411 is coupled to get as input the sequence of received samples and delay them properly to align them in time with the sequence of reconstructed input samples. A subtraction means 412 subtracts the sum Reconstr-Sum of the reconstructed input samples produced by all diversity combiners in the receiver excluding 40-I from the delayed samples to produce a sequence of modified samples. The produced sequence along with the sequence of the estimated logic levels are fed to the data pre-processing means 413 where the channel time responses and a combining vector are computed following the process described in respect with means 401 with the only difference of using the estimated logic levels instead of the known training sequence levels. The produced channel time responses and the combining vector are fed to the switch-A means 402 and the switch-B means 414 respectively. The switch-A means 402 and switch-B means 414 function as gating circuits and they feed the least squares means 403 with periodical fragments of data. Note that the data pre-processing means 413 may produce only the data fragments that are necessary for the operation of the least squares means 403. On the basis of each fragment of input data, the least squares means 403 produces a new updated value of the combiner weight vector w and stores it in the weight memory means 404. When the frequency domain diversity combiner 40-I is used for multi-carrier signals the said periodical fragments of data will be multi-carrier symbols periodically sampled. When 40-I is used for single carrier signals the means 406 and 410 will be omitted, while the channel estimation and equalization functions will take place in time domain.

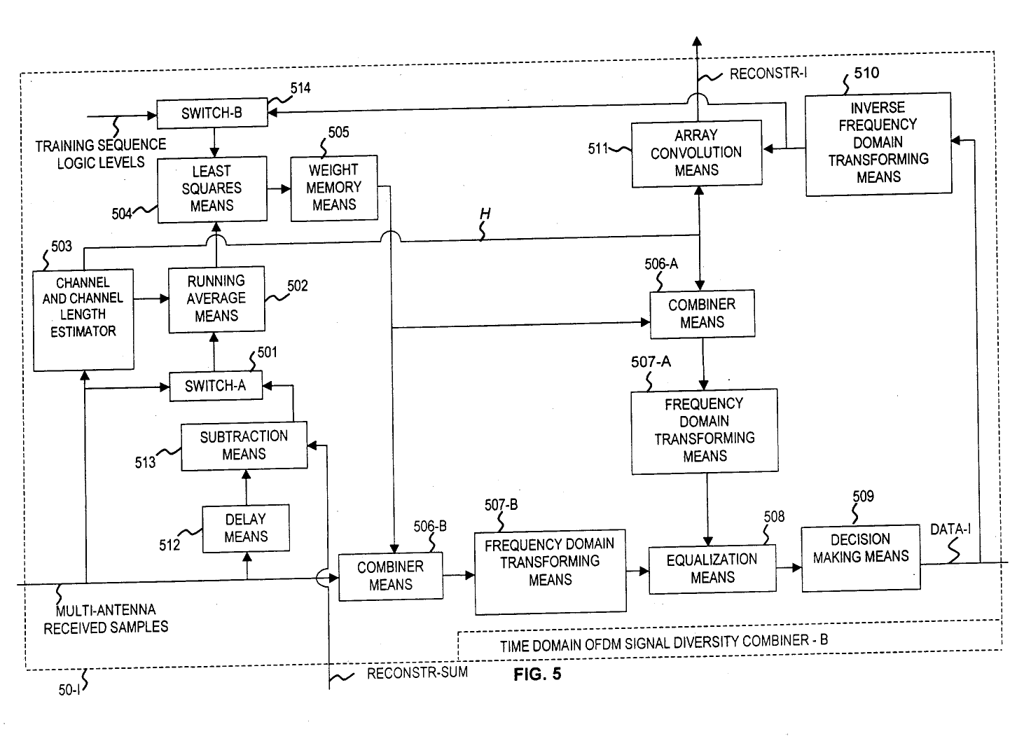

With reference to FIG. 5, a diversity combiner 50-I in accordance with a fourth preferred embodiment of the present invention performs the combining in time domain while it uses a time domain training sequence t for computing the combiner weight vector. The diversity combiner 50-I also can be used for multi-user communication. A channel estimator and channel length estimator means 503 is coupled to receive as input the sequence R of M-element samples r_{n,m}, m=1, . . . , M, n=1, . . . , N, respective to the known training sequence of length N from the antenna elements and produce estimates of the channel time responses H of the M channels respective to the antennas by employing a time-domain channel estimation technique based e.g. on the zero forcing or the minimum mean squared error criterion [5], as well as coarse estimates of the lengths lₘ, m=1, . . . , M of these M channels. A coarse estimate refers to the large components of each channel time response that are summing up for example to the 70% of the total channel energy and in practical cases the resulting length does not exceed the number 5. A running average means 502 is coupled to get as input the received sequence R through a switch-A 501 and the coarse channel length estimates and produces a running average sequence X based on the formula:

$${x}_{n , m} = {\sum }_{j = 1}^{{l}_{m}} {r}_{n + j , m} , m = 1 , … , M , n = 0 , … , N - {l}_{m} \qquad ( 7 )$$

where x_{n,m} denote the elements of X and l is the maximum of lₘ, m=1, . . . , M. A least squares means 504 is coupled to receive as input the known training sequence t through a switch-B means 515 and the sequence X and it produces a combiner weight vector w by minimizing the quantity ||Xw−t||². The resulting vector w is stored in a memory means 505. Further, the M channel responses of H are fed along with the combiner weight vector w resumed from the weight memory means 505 to a combiner means 506-A that produces a weighted channel time response. The weighted channel time response is subsequently fed to a frequency domain transforming means 507-A that produces a weighted channel frequency response to be used later by the equalization means 508. The sequence of M-element received samples respective to the information data sequence along with the combiner weight vector resumed from the weight memory means 505 are fed to the combiner means 506-B in order to produce a scalar sequence of weighted data samples. Note that the combiner means 506-A and 506-B are identical. The frequency domain transforming means 507-B transforms the sequence of weighted samples to a sequence of frequency domain samples. Note also that the frequency domain transforming means 507-A and 507-B are identical. A channel equalization means 508 is coupled to receive as input the said weighted channel frequency response and the sequence of the weighted data samples and produce as output a sequence of equalized data. A decision making means 509 is coupled to receive as input the sequence of equalized data and produces as output a sequence of estimated logic levels Data-I. The logic levels Data-I are fed to an inverse frequency domain transforming means 510 that produces a time domain estimated data sequence. An array convolution means 511 applies the convolution of the said time domain estimated data sequence with the channel time response matrix H and produces as output a sequence of M-element reconstructed input samples Reconstr-I. A delay means 512 is coupled to get as input the sequence of received samples and delay them properly to align them in time with the sequence of reconstructed input samples. A subtraction means 513 subtracts the sum Reconstr-Sum of the reconstructed input samples produced by all diversity combiners in the receiver excluding 50-I from the delayed received samples to produce a sequence of modified samples. The produced sequence is fed to the switch-A means 501 and subsequently to the running average means 502. Means 502 also receives as input the coarse length estimates of the time domain channel responses and produces a running average that is fed to the least squares means 504. The switch-A means 501 and switch-B means 514 function as gating circuits for the sequence of modified samples and the said time domain estimated data sequence coming from means 511, respectively, and they feed means 502 and 504 with periodical fragments of data. On the basis of each fragment of input data, the least squares means 504 produces a new updated value of the combiner weight vector w and stores it in the weight memory means 505. When the frequency domain diversity combiner 50-I is used for multi-carrier signals the said periodical fragments of data will be multi-carrier symbols periodically sampled. When 50-I is used for single carrier signals the means 507 and 510 will be omitted and the channel estimation and equalization functions will take place in time domain.

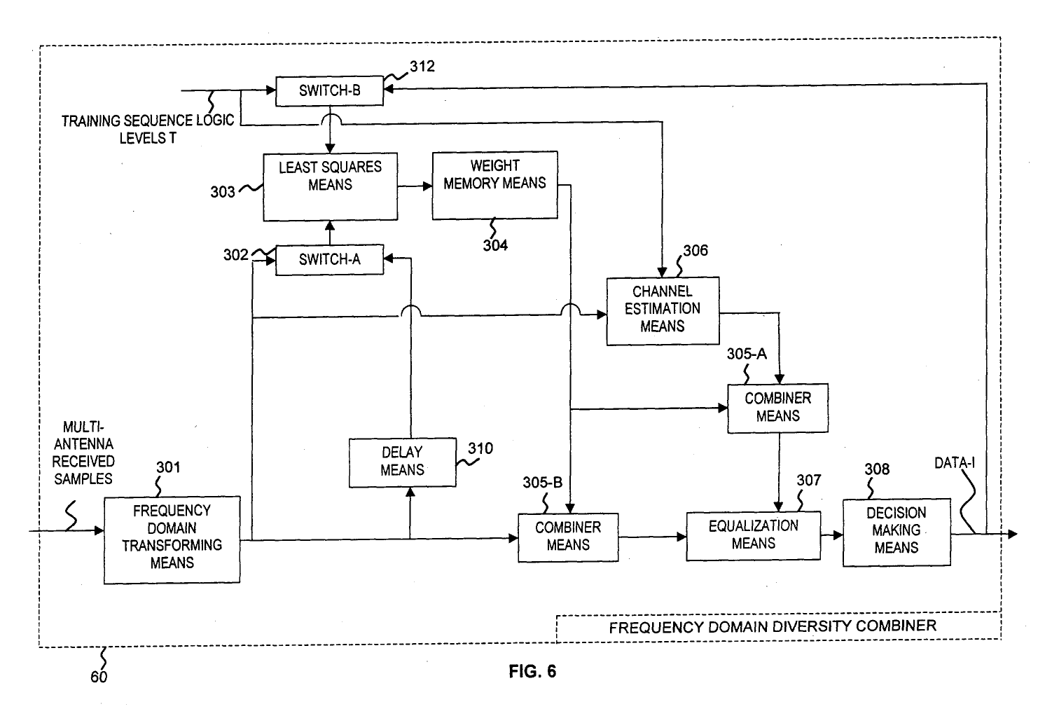

With reference to FIG. 6, a diversity combiner 60 in accordance with a fifth preferred embodiment of the present invention is appropriate for co-channel interference (CCI) in a wireless communication system comprising a single transmitter and a receiving device. The diversity combiner 60 is a reduced version of the diversity combiner 30-I described with reference to FIG. 3. In particular, the array multiplier means 309 and the subtraction means 311 may be omitted.

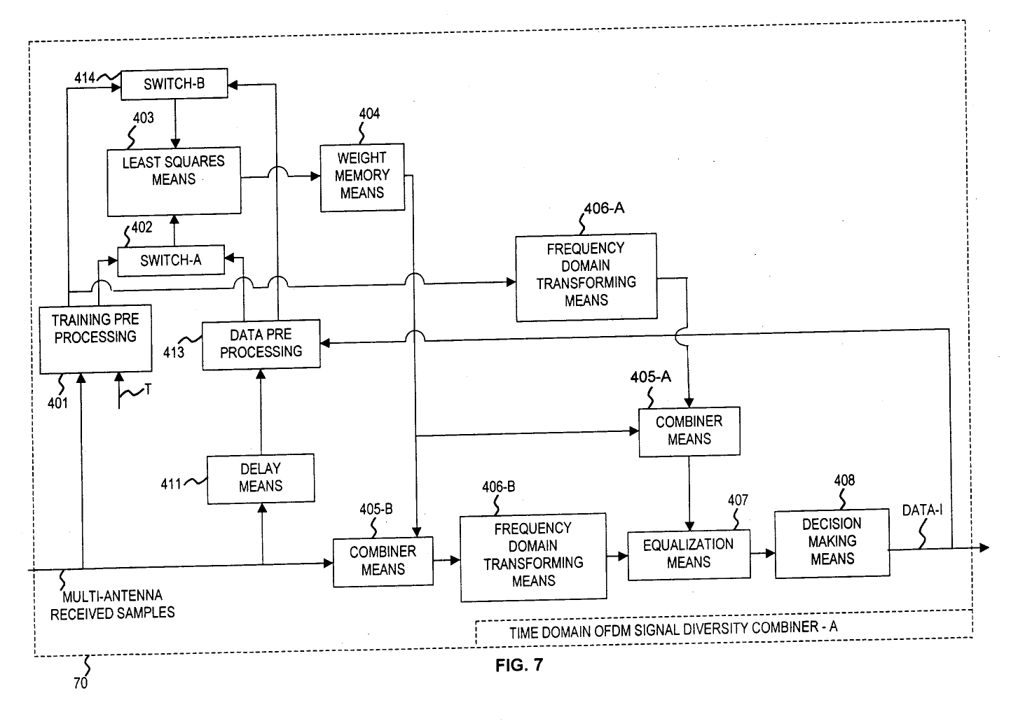

With reference to FIG. 7, a diversity combiner 70 in accordance with a sixth preferred embodiment of the present invention is appropriate for co-channel interference (CCI) in a wireless communication system comprising a single transmitter and a receiving device. The diversity combiner 70 is a reduced version of the diversity combiner 40-I described with reference to FIG. 4. In particular, the array multiplier means 409, the inverse frequency transforming means 410 and the subtraction means 412 may be omitted.

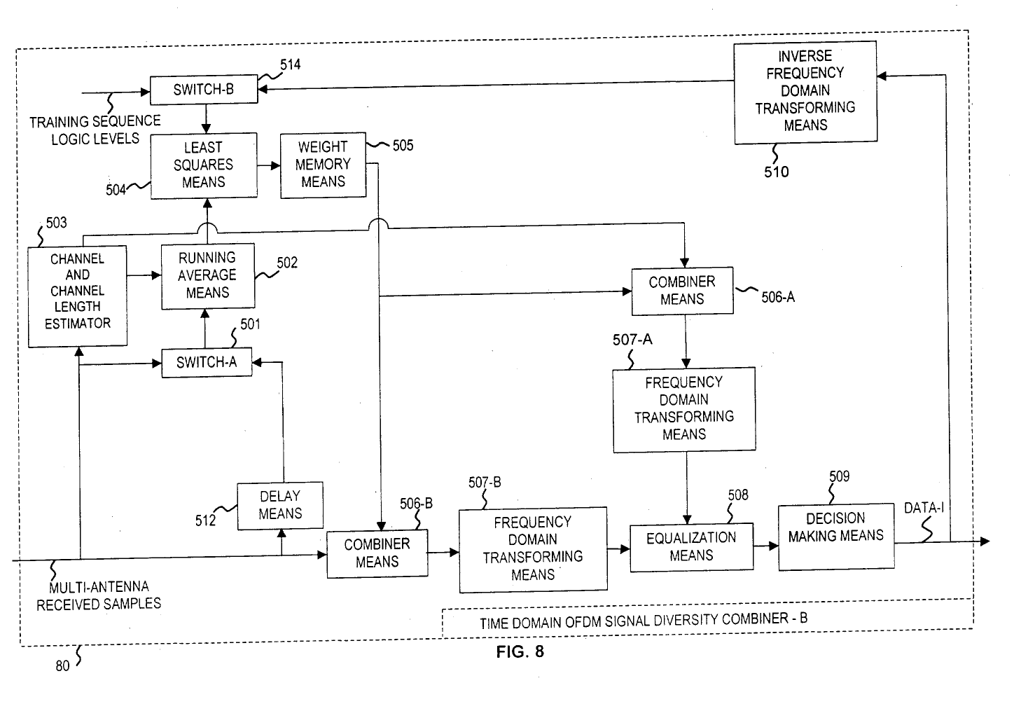

With reference to FIG. 8, a diversity combiner 80 in accordance with a seventh preferred embodiment of the present invention is appropriate for co-channel interference (CCI) in a wireless communication system comprising a single transmitter and a receiving device. The diversity combiner 80 is a reduced version of the diversity combiner 50-I described with reference to FIG. 5. In particular, the array convolution means 511 and the subtraction means 513 may be omitted.

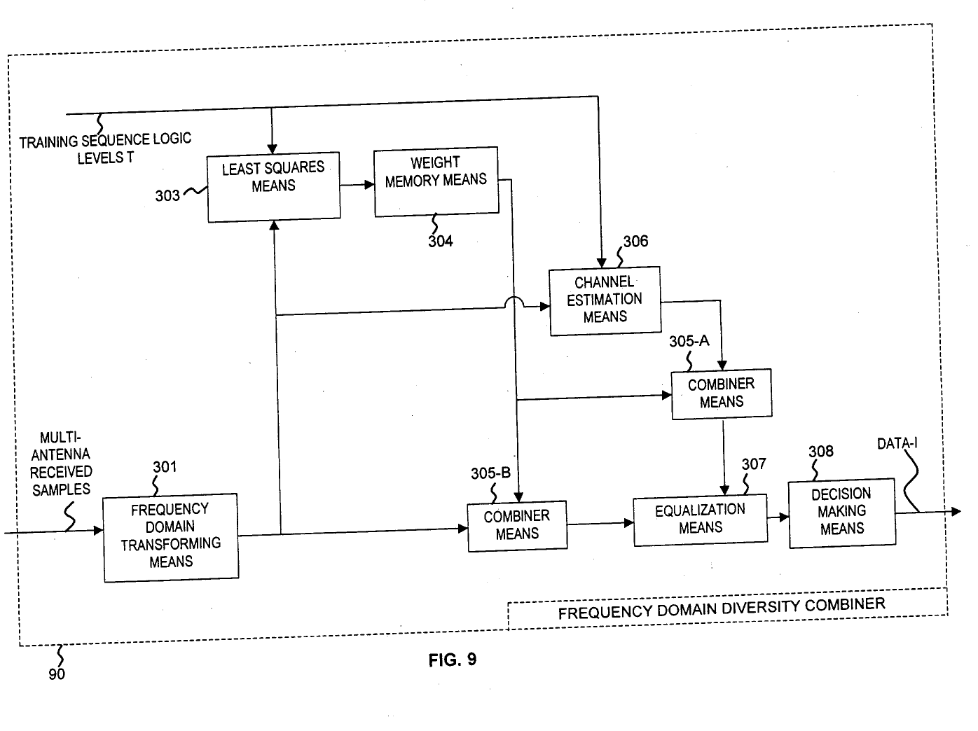

With reference to FIG. 9, a diversity combiner 90 in accordance with an eighth preferred embodiment of the present invention computes a combining weight vector on the basis of the received training sequence samples only. This diversity combiner is appropriate for communication systems where the directionality and other communication parameters do not change substantially within a frame. In this case, the diversity combiner 90 is appropriate for suppressing co-channel interference (CCI) in a single user wireless communication system, as well as for supporting multi-user wireless communication. The diversity combiner 90 is a reduced version of the diversity combiner 30-I described with reference to FIG. 3. In particular, the means 309 and 311 that are related to the input reconstructed signals, as well as the means 302, 310 and 312 that are related to the update of the combining weight vector based on the information data signals may be omitted.

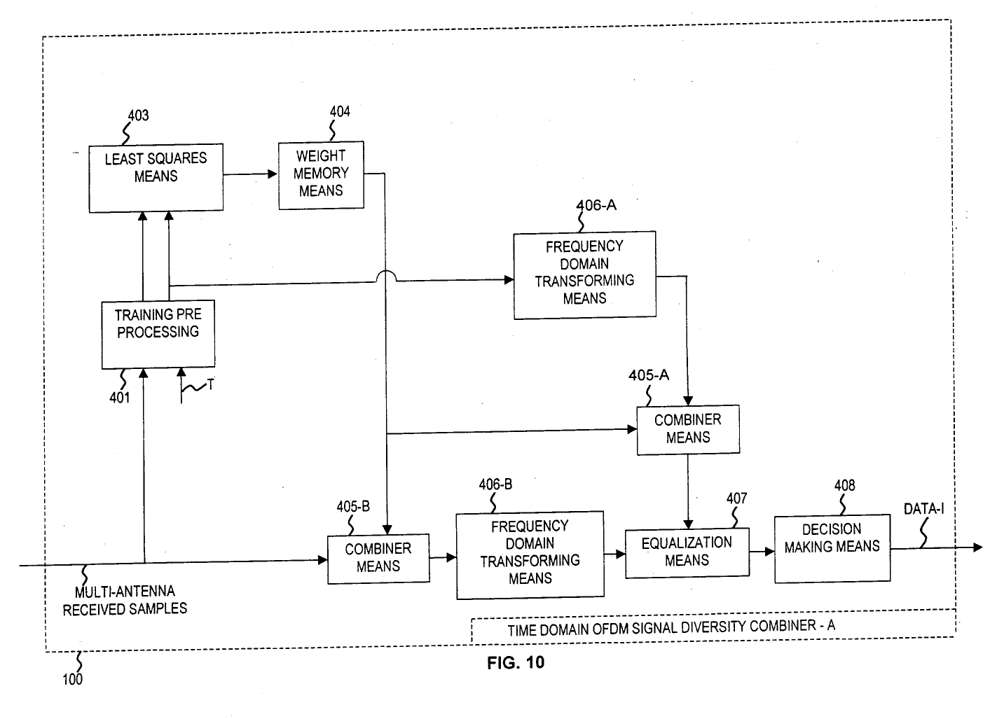

With reference to FIG. 10, a diversity combiner 100 in accordance with a ninth preferred embodiment of the present invention computes a combining weight vector on the basis of the received training sequence samples only. This diversity combiner too is appropriate for communication systems where the directionality and other communication parameters do not change substantially within a frame. In this case, 100 is appropriate for suppressing co-channel interference (CCI) in a single user wireless communication system, as well as for supporting multi-user wireless communication. The diversity combiner 100 is a reduced version of the diversity combiner 40-I described with reference to FIG. 4. In particular, the means 409, 410 and 412 that are related to the input reconstructed signals, as well as the means 402, 411 and 414 that are related to the update of the combining weight vector based on the information data signals may be omitted.

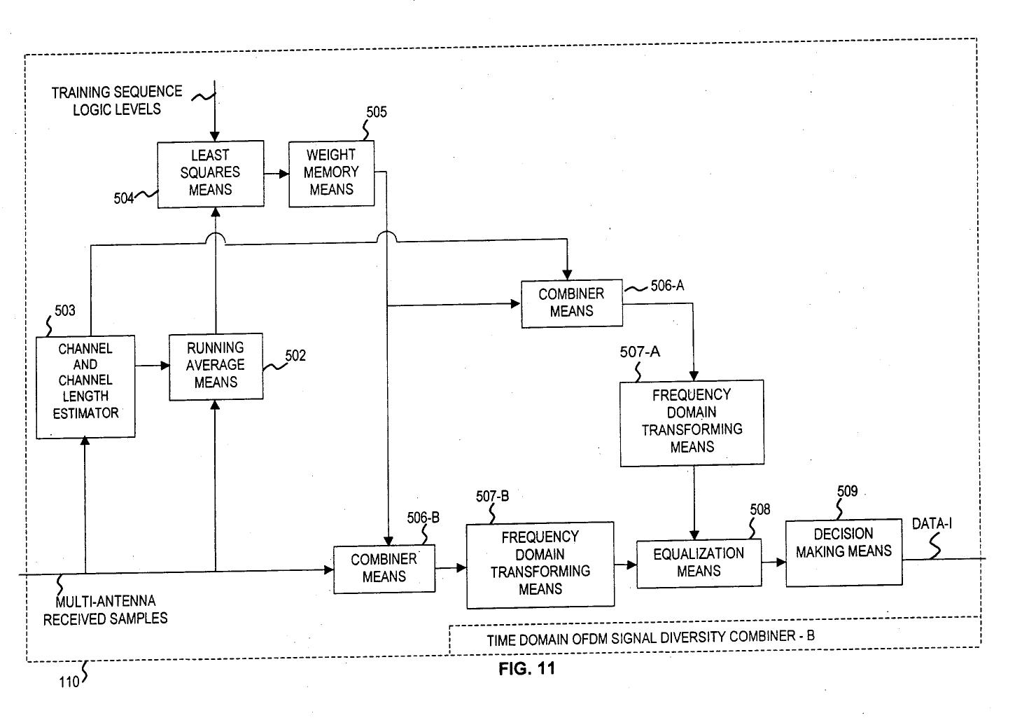

With reference to FIG. 11, a diversity combiner 110 in accordance with preferred embodiment of the present invention computes a combining weight vector on the basis of the received training sequence samples only. This diversity combiner too is appropriate for communication systems where the directionality and other communication parameters do not change substantially within a frame. In this case, the diversity combiner 110 is appropriate for suppressing co-channel interference (CCI) in a single user wireless communication system, as well as for supporting multi-user wireless communication. The diversity combiner 110 is a reduced version of the diversity combiner 50-I described with reference to FIG. 5. In particular, the means 511 and 513 that are related to the input reconstructed signals, as well as the means 501, 510, 512 and 514 that are related to the update of the combining weight vector based on the information data signals may be omitted.

### References

[1] S. Haykin, Adaptive filter theory, Prentice Hall, Englewood Cliffs, 2^{nd} Ed., 1991.

[2] S.Bulumulla, S.Kassam and S.Venkatesh, “An adaptive diversity receiver for OFDM in fading channels”, In Proc. International Conference on Communications, pp.1325-1329, 1998.

[3] J.Razavilar, F. Rashid-Farrokhi and K. J. R. Liu, “Software Radio Architecture with Smart Antennas: A Tutorial on Algorithms and Complexity”, IEEE Trans. on Selected Areas in Communications, Vol. 17, No 4, pp.662-676, April 1999.

[4] S.Kapoor, D. J.Marchok and Y -F.Huang, “Adaptive Interference Suppression in Multiuser Wireless OFDM Systems Using Antenna Arrays”, IEEE Trans. on Signal Processing, Vol. 47, No 12, pp.3381-3391, December 1999.

[5] S. Verdú, Multiuser Detection, Cambridge Univ. Press, Cambridge, 1998.

1. A method for diversity combining a wireless communication system comprising at least one transmitting devices sharing essentially the same frequency spectrum and a receiving device having an antenna array, where the said transmitting and receiving devices are synchronized so that:
the transmitting devices may transmit signals and the receiving device receives the signals simultaneously;
the receiving device is aware of the starting time instants and ending time instants of the training sequences and the information data sequences of all of the transmitting devices;
said method comprising steps of:
transmitting a signal characterized by a frame having a known training sequence and an information data sequence;
receiving said signal from an antenna array having multiple antennas;
processing said training sequence received from each one of said multiple antenna using a least square algorithm to obtain and to store a weight vector; and
combining said information data sequence with reference to said weight vector for controlling the antenna array in order to achieve directional reception and suppress co-channel interference.

2. The method of claim 1 including processing of the received training sequence samples and the received information data samples respective to at least one transmitting device:
wherein said processing of the received training samples respective to each one of the transmitting devices comprises the steps of:
computing a combiner weight vector using a least squares algorithm based on the sequence of received training samples and the known training sequence,
estimating the channel responses respective to the antenna elements of the antenna array on the basis of the received training samples and the known training sequence,
estimating a weighted channel response on the basis of the channel responses and the combiner weight vector, and
storing the combiner weight vector and said weighted channel response; and
wherein said processing of the received information data samples respective to each transmitting device comprises the steps of:
resuming the combiner weight vector and the weighted channel response,
computing a sequence of weighted samples on the basis of the received information data samples and the combiner weight vector,
equalizing the sequence of weighted samples to produce a sequence of equalized data samples by using [the] said weighted channel response,
computing a sequence of estimated logic levels based on the sequence of equalized data samples,
producing a sequence of reconstructed input samples based on the sequence of estimated logic levels and said channel responses respective to the antenna elements of the antenna array,
producing a sequence of modified information data samples based on the received information data samples and the reconstructed input samples respective to other transmitting devices, and
updating the combiner weight vector using [the] said least squares algorithm based on the sequence of modified information data samples and the sequence of estimated logic levels.

3. The method of claim 2, wherein the updating of the combiner weight vectors respective to the transmitting devices is executed using time sharing of the least squares algorithm.

4. The method of claim 2:
wherein the signals transmitted by the transmitting devices are orthogonal frequency division multiplexing (OFDM) signals;
wherein the processing of the received training samples further comprises the steps of:
producing a sequence of frequency domain training samples based on the received training samples and feeding the produced sequence to the least squares algorithm, and
estimating the channel responses refers to the frequency domain channel responses; and
wherein the processing of the received information data samples further comprises steps of:
producing a sequence of frequency domain information data samples based on the received information data samples and feeding the produced sequence to the least squares algorithm, and
producing a sequence of modified information data samples comprising sub-steps of:
producing a first sequence of data blocks by fragmenting the sequence of the frequency domain information data samples into equally sized blocks,
producing a second sequence of data blocks by sampling periodically the first sequence of data blocks,
producing a third sequence of data blocks by delaying the second sequence of data blocks to synchronize [their] respective data samples with the sequence of reconstructed input samples, and
producing a sequence of modified data blocks by subtracting the reconstructed input samples respective to other transmitting devices from the data samples respective to the third sequence of data blocks.

5. The method of claim 2:
wherein the signals transmitted by the transmitting devices are orthogonal frequency division multiplexing (OFDM) signals;
wherein the step of computing the combiner weight vector comprises sub-steps of:
estimating the channel time responses respective to the antenna elements of the antenna array based on the received training samples and the known training sequence,
computing a sequence of combining samples as a function of said channel time responses;
using the least squares algorithm based on the estimated channel time responses and the sequence of combining samples;
wherein the step of estimating the channel responses refers to the time domain channel responses and further comprises a sub-step of transforming these channel responses to the frequency domain using a frequency domain transforming means;
wherein the processing of the received information data samples further comprises a step of producing a sequence of frequency domain information data samples based on the sequence of weighted samples and use the produced sequence for the equalization step;
wherein the step of producing a sequence of reconstructed input samples further comprises a sub-step of producing a sequence of time domain information data samples based on the sequence of estimated logic levels and the frequency domain channel responses;
wherein the step of producing a sequence of modified information data samples comprises sub-steps of:
producing a first sequence of data blocks by fragmenting the sequence of the frequency domain information data samples into equally sized blocks,
producing a second sequence of data blocks by sampling periodically the first sequence of data blocks,
producing a third sequence of data blocks by delaying the second sequence of data blocks to synchronize their respective data samples with the sequences of reconstructed input samples, and
producing a sequence of modified data blocks by subtracting the reconstructed input samples respective to other transmitting devices from the data samples respective to the third sequence of data blocks; and
wherein the step of combining the update vector comprises sub-steps of:
estimating the channel time responses respective to the antenna elements of the antenna array based on the sequence of modified data blocks and the respective estimated logic levels,
computing a sequence of combining samples as a function of said channel time responses, and
using the least squares algorithm based on the estimated channel time responses and the sequence of combining samples.

6. The method of claim 2:
wherein the signals transmitted by the transmitting devices are orthogonal frequency division multiplexing (OFDM) signals;
wherein the steps of computing the combiner weight vector comprises sub-steps of:
estimating the channel time responses respective to the antenna elements of the antenna array and the length of these channel time responses based on the received training samples and the known training sequence,
producing running average sequences respective to the antenna elements of the antenna array based on the received training samples and the estimated channel time response length, and
using the least squares algorithm based on the running average sequences and the training sequence logic levels;
wherein the step of estimating the channel responses refers to the time domain channel responses and further comprises a sub-step of transforming the weighted estimated channel response to the frequency domain by using a frequency domain transforming means;
wherein the processing of the received information data samples further comprises a step of producing a sequence of frequency domain information data samples based on the sequence of weighted samples and use the produced sequence for the equalization step;
wherein the step of producing a sequence of reconstructed input samples further comprises a sub-step of producing a sequence of time domain information data samples based on the sequence of estimated logic levels;
wherein the step of producing a sequence of modified information data samples further comprises sub-steps of:
producing a first sequence of data blocks by fragmenting the sequence of the frequency domain information data samples into equally sized blocks,
producing a second sequence of data blocks by sampling periodically the first sequence of data blocks,
producing a third sequence of data blocks by delaying the second sequence of data blocks to synchronize [their] respective data samples with the sequence of reconstructed input samples, and
producing a sequence of modified data blocks by subtracting the reconstructed input samples respective to other transmitting devices from the data samples respective to the third sequence of data blocks; and
wherein the step of combining the update vector comprises sub-steps of:
producing running average sequences respective to the antenna elements of the antenna array based on the modified information data samples and the estimated channel time response length, and
using the least squares algorithm based on the running average sequences and [the] said sequence of time domain information data samples based on the sequence of estimated logic levels.

7. The method of claim 1:
wherein the wireless communication system comprising a transmitting device and a receiving device and the transmitting device transmits an orthogonal frequency division multiplexing (OFDM) signal, where the said method includes processing of the received training sequence samples and processing of the received information data samples;
wherein the said processing of the received training samples comprises the steps of:
producing a sequence of frequency domain training samples based on the received training samples,
computing a combiner weight vector using a least squares algorithm based on the sequence of frequency domain training samples and the known training sequence,
estimating the channel responses respective to the antenna elements of the antenna array on the basis of the frequency domain training samples and the known training sequence;
computing a weighted channel response on the basis of the estimated channel responses and the combiner weight vector, and
storing the combiner weight vector and the said weighted channel response; and
wherein the said processing of the received information data samples comprises the steps of:
resuming the combiner weight vector and the weighted channel response,
producing a sequence of frequency domain information data samples based on the received information data samples,
computing a sequence of weighted samples on the basis of the frequency domain information data samples and the combiner weight vector,
equalizing the sequence of weighted samples to produce a sequence of equalized data samples by using [the] said weighted channel response,
computing a sequence of estimated logic levels based on the sequence of equalized data samples,
producing a sequence of delayed information data samples based on the received information data samples, and
updating the combiner weight vector using [the] said least squares algorithm based on the sequence of delayed information data samples and the sequence of estimated logic levels.

8. The method of claim 1:
wherein the wireless communication system comprising a transmitting device and a receiving device and the transmitting device transmits an orthogonal frequency division multiplexing (OFDM) signal, where said method includes processing of the received training sequence samples and processing of the received information data samples;
wherein said processing of the received training samples comprising the steps of:
estimating the channel time responses respective to the antenna elements of the antenna array based on the received training samples and the known training sequence,
computing a sequence of combining samples as a function of [the] said channel time responses,
computing a combiner weight vector using the least squares algorithm based on the estimated channel time responses and the sequence of combining samples,
producing a sequence of channel frequency responses based on the sequence of [the] said estimated channel time responses by using a frequency domain transforming means,
computing a weighted channel response on the basis of said channel frequency responses and the combiner weight vector, and
storing the combiner weight vector and the weighted channel response; and
wherein the said processing of the received information data samples comprising the steps of:
resuming the combiner weight vector and the weighted channel response,
computing a sequence of weighted samples on the basis of the received information data samples and the combiner weight vector,
producing a sequence of frequency domain information data samples based on the sequence of weighted samples,
equalizing the sequence of weighted samples to produce a sequence of equalized data samples by using [the] said weighted channel response,
computing a sequence of estimated logic levels based on the sequence of equalized data samples,
producing a sequence of delayed information data samples based on the received information data samples,
estimating the channel time responses respective to the antenna elements of the antenna array based on the sequence of the delayed information data samples and the respective estimated logic levels,
computing a sequence of combining samples as a function of the estimated channel time responses, and
updating the combiner weight vector using the least squares algorithm based on the estimated channel time responses and the sequence of combining samples.

9. The method of claim 1,
wherein the wireless communication system comprising a transmitting device and a receiving device and the transmitting device transmits an orthogonal frequency division multiplexing (OFDM) signal, where said method includes processing of the received training sequence samples and processing of the received information data samples;
wherein said processing of the received training samples comprises the steps of:
estimating the channel time responses respective to the antenna elements of the antenna array and the length of these channel time responses based on the received training samples and the known training sequence,
producing running average sequences respective to the antenna elements of the antenna array based on the received training samples and the estimated channel time response length,
computing a combiner weight vector using the least squares algorithm based on the running average sequences and the training sequence logic levels,
computing a weighted channel time response on the basis of said channel time responses and the combiner weight vector,
producing a weighted channel frequency response based on said weighted channel time response by using a frequency domain transforming means, and
storing the combiner weight vector and the weighted channel frequency response; and
wherein said processing of the received information data samples comprising the steps of:
resuming the combiner weight vector and the weighted channel frequency response,
computing a sequence of weighted samples on the basis of the received information data samples and the combiner weight vector,
producing a sequence of frequency domain information data samples based on the sequence of weighted samples,
equalizing the sequence of weighted samples to produce a sequence of equalized data samples by using the said weighted frequency channel response,
computing a sequence of estimated logic levels based on the sequence of equalized data samples, as well as transforming these logic levels to produce a time domain sequence of logic levels,
producing a sequence of delayed information data samples based on the received information data samples,
producing running average sequences respective to the antenna elements of the antenna array based on the delayed information data samples and the estimated channel time response length, and
updating the combiner weight vector using the least squares algorithm based on the running average sequences and the said time domain sequence of logic levels.

10. The method of claim 1 including processing of the received training sequence samples and the received information data samples respective to at least one transmitting device,
wherein the said processing of the received training samples respective to each transmitting device comprises the steps of:
producing a sequence of frequency domain training samples based on the received training samples,
computing a combiner weight vector using a least squares algorithm based on the sequence of frequency domain training samples and the known training sequence,
estimating the channel responses respective to the antenna elements of the antenna array on the basis of the frequency domain training samples and the known training sequence,
computing a weighted channel response on the basis of the estimated channel responses and the combiner weight vector, and
storing the combiner weight vector and said weighted channel response; and
wherein said processing of the received information data samples respective to each transmitting device comprises the steps of:
resuming the combiner weight vector and the said weighted channel response,
producing a sequence of frequency domain information data samples based on the received information data samples,
computing a sequence of weighted samples on the basis of the frequency domain information data samples and the combiner weight vector,
equalizing the sequence of weighted samples to produce a sequence of equalized data samples by using said weighted channel response, and
computing a sequence of estimated logic levels based on the sequence of equalized data samples.

11. The method of claim 1 including processing of the received training sequence samples and the received information data samples respective to at least one transmitting device,
wherein said processing of the received training samples respective to each transmitting device comprises the steps of:
estimating the channel time responses respective to the antenna elements of the antenna array based on the received training samples and the known training sequence,
computing a sequence of combining samples as a function of said channel time responses,
computing a combiner weight vector using the least squares algorithm based on the estimated channel time responses and the sequence of combining samples,
producing a sequence of channel frequency responses based on the sequence of said estimated channel time responses by using a frequency domain transforming means,
computing a weighted channel response on the basis of said channel frequency responses and the combiner weight vector,
storing the combiner weight vector and the weighted channel response; and
wherein the processing of the received information data samples respective to each transmitting device comprises the steps of:
resuming the combiner weight vector and said weighted channel response,
computing a sequence of weighted samples on the basis of the received information data samples and the combiner weight vector,
producing a sequence of frequency domain information data samples based on the sequence of weighted samples,
equalizing the sequence of weighted samples to produce a sequence of equalized data samples by using the said weighted channel response, and
computing a sequence of estimated logic levels based on the sequence of equalized data samples;

12. The method of claim 1 including processing of the received training sequence samples and the received information data samples respective to at least one transmitting device:
wherein the said processing of the received training samples respective to each transmitting device comprises the steps of:
estimating the channel time responses respective to the antenna elements of the antenna array and the length of these channel time responses based on the received training samples and the known training sequence,
producing running average sequences respective to the antenna elements of the antenna array based on the received training samples and the estimated channel time response length,
computing a combiner weight vector using the least squares algorithm based on the running average sequences and the training sequence logic levels,
computing a weighted channel time response on the basis of the said channel time responses and the combiner weight vector,
producing a weighted channel frequency response based on the said weighted channel time response by using a frequency domain transforming means, and
storing the combiner weight vector and the weighted channel frequency response; and
wherein said processing of the received information data samples respective to each transmitting device comprises the steps of:
resuming the combiner weight vector and [the] said weighted channel response,
computing a sequence of weighted samples on the basis of the received information data samples and the combiner weight vector,
producing a sequence of frequency domain information data samples based on the sequence of weighted samples,
equalizing the sequence of weighted samples to produce a sequence of equalized data samples by using [the] said weighted channel frequency response, and
computing a sequence of estimated logic levels based on the sequence of equalized data samples.

13. Apparatus for diversity combining in a wireless communication system comprising a plurality of transmitting devices sharing essentially the same frequency spectrum and a receiving device having an antenna array, where each transmitting device transmits a signal characterized by a frame comprising a known training sequence and an information data sequence, and said transmitting and receiving devices are synchronized so that:
the transmitting devices may transmit their signals simultaneously, and
the receiving device is aware of the starting time instants and ending time instants of the training sequences and the information data sequences of all transmitting devices;
wherein said apparatus includes means for processing the received training sequence samples and the received information data samples respective to at least one transmitting device;
wherein the said processing of the received training samples respective to each transmitting device comprises the steps of:
computing a combiner weight vector using a least squares algorithm based on the sequence of received training samples and the known training sequence,
estimating the channel responses respective to the antenna elements of the antenna array on the basis of the received training samples,
computing a weighted channel response on the basis of said channel responses and the combiner weight vector, and
storing the combiner weight vector and [the] said weighted channel response; and
wherein the said means respective to each transmitting device for processing the received information data samples executing a sequence of steps comprising:
resuming the combiner weight vector and said weighted channel response,
computing a sequence of weighted samples on the basis of the received information data samples and the combiner weight vector,
equalizing the sequence of weighted samples to produce a sequence of equalized data samples by using [the] said weighted channel response,
computing a sequence of estimated logic levels based on the sequence of equalized samples,
producing a sequence of reconstructed input samples based on the sequence of estimated logic levels and [the] said estimated channel responses,
producing a sequence of modified information data samples based on the received information data samples and the reconstructed input samples respective to other transmitting devices, and
updating the combiner weight vector using [the] said least squares algorithm based on the sequence of modified information data samples and the sequence of estimated logic levels.
